(19) United States
(12) Patent Application Publication
(10) Pub. No.: US 2015/0033050 A1
(43) Pub. Date: Jan. 29, 2015

(54) SEMICONDUCTOR INTEGRATED CIRCUIT AND COMPUTING DEVICE INCLUDING THE SAME

(71) Applicant: SAMSUNG ELECTRONICS CO., LTD, Suwon-si (KR)

(72) Inventors: Amjad QADAN, Plano, TX (US); Neil PANCHAL, Round Rock, TX (US)

(73) Assignee: SAMSUNG ELECTRONICS CO., LTD, Suwon-si (KR)

(21) Appl. No.: 13/950,729

(22) Filed: Jul. 25, 2013

(51) Int. Cl. H01L 23/58; G06F 1/32

(52) U.S. Cl. CPC H01L 23/58; G06F 1/3203
USPC 713/322; 327/564

(57) ABSTRACT

A semiconductor integrated circuit and a computing system including the same are provided. The semiconductor integrated circuit includes: an integrated clock gating cell including a clock output node; and clock-based cells each including a clock input node. The clock output node of the integrated clock gating cell and the clock input nodes of the clock-based cells are aligned on a straight line and commonly connected to a clock gating path.

### BACKGROUND

Apparatuses and methods consistent with exemplary embodiments relate to semiconductor devices and, more particularly, to a semiconductor integrated circuit and a computing device including the semiconductor device.

With the advance in semiconductor manufacturing technology, semiconductor integrated circuits have been widely used. A semiconductor integrated circuit is a device in which a plurality of semiconductor elements is integrated into a single chip. A semiconductor integrated circuit occupies a smaller area and consumes less power than related art semiconductor devices.

As the development of semiconductor integrated circuits enables semiconductor devices to be light in weight and small in size, mobile devices have been developed. A mobile device, such as a smart phone or a smart pad, is a semiconductor device that can be carried by a user. In order to achieve portability, a mobile device uses a battery as a power source. The battery may supply a limited amount of power source due to its limitation in size and weight. Various studies have been conducted to increase operating time of mobile devices and reduce power consumption of semiconductor integrated circuits.

One of the studies for reducing power consumption of semiconductor integrated circuits is associated with clock gating. The clock gating is a technique to control clocks used in a semiconductor integrated circuit. As an example of the clock gating, when a specific section of a semiconductor integrated circuit is not used, a clock provided to the unused section may be blocked. The clock is selectively blocked to reduce power consumption of the semiconductor integrated circuit.

### SUMMARY

Exemplary embodiments provide a semiconductor integrated circuit and a computing system including the same.

According to an aspect of an exemplary embodiment, there is provided a semiconductor integrated circuit including: an integrated clock gating cell including a clock output node; and clock-based cells each including a clock input node. The clock output node of the integrated clock gating cell and the clock input nodes of the clock-based cells are aligned on a straight line and commonly connected to a clock gating path.

In an exemplary embodiment, the integrated clock gating cell and the clock-based cells may be adjacent to each other.

In an exemplary embodiment, the clock gating path may include a wire.

In an exemplary embodiment, the clock-based cells may include registers each operating based on a clock.

In an exemplary embodiment, the clock-based cells may include flip-flops each operating based on a clock.

In an exemplary embodiment, the semiconductor integrated circuit may further include second clock-based cells each including a second clock input node. The second clock input nodes of the second clock-based cells may be aligned on a straight line and commonly connected to a second clock gating path. The second clock gating path may be electrically connected to the clock output node of the integrated clock gating cell.

In an exemplary embodiment, the integrated clock gating cell and the clock-based cells may constitute a first cell column, and the second clock-based cells may constitute a second cell column parallel to the first cell column.

In an exemplary embodiment, the semiconductor integrated circuit may further include a second integrated clock gating cell including a second clock input node at a first end and a second clock output node at a second end; and second clock-based cells each including a third clock input node. The second clock output node of the second integrated clock gating cell and the third clock input nodes of the second clock-based cells may be aligned on a straight line and commonly connected to a second clock gating path.

In an exemplary embodiment, the second clock input node of the second integrated clock gating cell may be electrically connected to the clock output node of the integrated clock gating cell.

In an exemplary embodiment, the second clock input node of the second integrated clock gating cell may be electrically connected to the clock output node of one of the clock-based cells.

In an exemplary embodiment, one of the clock-based cells may include the clock input node at a first end and a second clock output node at a second end.

In an exemplary embodiment, the semiconductor integrated circuit may further include second clock-based cells each including a second clock input node. The second clock input nodes of the second clock-based cells may be aligned with the second clock output node of the second integrated clock gating cell on a straight line.

In an exemplary embodiment, the integrated clock gating cell, the second integrated clock gating cell, the clock-based cells, and the second clock-based cells may be adjacent to each other on a straight line to constitute a single cell column.

According to an aspect of another exemplary embodiment, there is provided a computing system including: a main memory; a storage; a processor configured to control the main memory and the storage; a modem configured to communicate with a first external entity according to a control of the processor; a user interface configured to receive a signal from a second external entity and output a signal to the second external entity according to a control of the processor; and a clock generating circuit configured to generate a clock signal and transmit the generated clock signal to at least one of the processor and the modem. At least one of the processor and the modem includes an aligned clock gating tree structure operating in response to the clock signal. The aligned clock gating tree structure includes an integrated clock gating cell to receive the clock signal and output a gated clock signal and a plurality of clock-based cells to receive the gated clock signal from the integrated clock gating cell. The integrated clock gating cell and the plurality of clock-based cells are concentrically placed such that length of a longest clock gating path along which the gating clock signal is transmitted to the clock-based cells from the integrated clock gating cell is equal to or less than a reference value.

In an exemplary embodiment, an output node of the gated clock signal of the integrated clock gating cell and input nodes of the gated clock signal of the clock-based cells may be aligned on a straight line to be commonly connected to the clock gating path.

According to an aspect of another exemplary embodiment, there is provided a semiconductor integrated circuit including: a first integrated clock gating cell configured to output a gated clock signal along a first clock gating path that is a straight line; and first clock-based cells each configured to receive the output gated clock signal along the first clock gating path, wherein the first integrated clock gating cell and the first clock-based cells are arranged such that a longest transmission length on the first clock gating path along which the gated clock signal is transmitted to the first clock-based cells from the first integrated clock gating cell is equal to or less than a reference value.

In an exemplary embodiment, the clock based cells and/or the integrated clock gating cell in a column are placed intensively excluding another clock based cell or integrated clock gating cell using another clock signal different from the clock signal therebetween.

In an exemplary embodiment, the reference value is a value which is determined such that the clock signal has a clock skew which are identified by the application processor 110 with a predetermined margin.

### BRIEF DESCRIPTION OF THE DRAWINGS

Exemplary embodiments will become more apparent in view of the attached drawings and accompanying detailed description. Exemplary embodiments depicted therein are provided by way of example, not by way of limitation, wherein like reference numerals refer to the same or similar elements. The drawings are not necessarily to scale, emphasis instead being placed upon illustrating aspects of inventive concepts.

FIG. 1 is a block diagram of a mobile device according to an exemplary embodiment;

FIG. 2 illustrates a clock gating structure according to an exemplary embodiment;

FIG. 3 illustrates a clock gating structure according to another exemplary embodiment;

FIG. 4 is a flowchart illustrating a method of forming a semiconductor integrated circuit according to an exemplary embodiment;

FIG. 5 is a flowchart more specifically illustrating the operation of determining whether alignment is to be executed in FIG. 4;

FIG. 6 is a flowchart more specifically illustrating the operation of placing an integrated clock gating cell and fanned-out cells in FIG. 4;

FIG. 7 is a flowchart more specifically illustrating the operation of forming a semiconductor integrated circuit in FIG. 4;

FIG. 8 illustrates an aligned clock gating structure according to another exemplary embodiment;

FIG. 9 illustrates an aligned clock gating structure according to another exemplary embodiment;

FIG. 10 is a block diagram of a mobile device according to another exemplary embodiment; and

FIG. 11 is a block diagram of a computing system according to an exemplary embodiment.

### DETAILED DESCRIPTION OF EXEMPLARY EMBODIMENTS

Exemplary embodiments will now be described more fully with reference to the accompanying drawings. Exemplary embodiments may, however, be embodied in many different forms and should not be construed as limited to exemplary embodiments set forth herein. Rather, these exemplary embodiments are provided so that this description will be thorough and complete, and will fully convey the inventive concept to those of ordinary skill in the art. In the drawings, the thicknesses of layers and regions are exaggerated for clarity. Furthermore, it is understood that although the terms “first”, “second”, “third”, etc., may be used herein to describe various elements, these elements should not be limited by these terms. These terms are only used to distinguish one element from another. Thus, a first element discussed below could be termed a second element without departing from the teachings of exemplary embodiments. Also, expressions such as “at least one of,” when preceding a list of elements, modify the entire list of elements and do not modify the individual elements of the list.

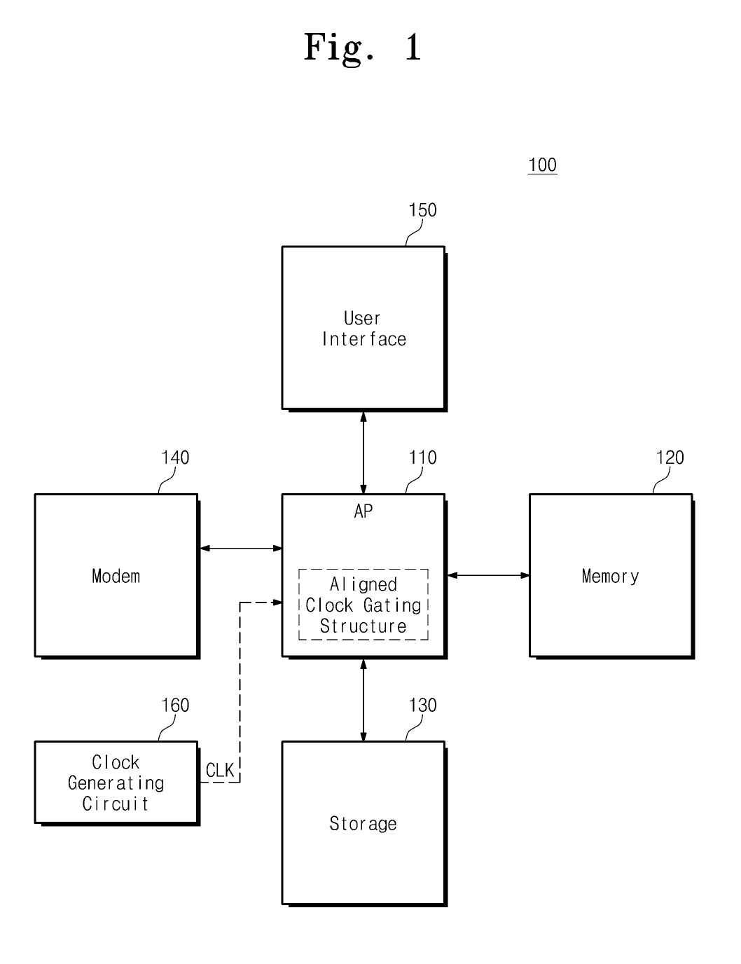

FIG. 1 is a block diagram of a mobile device 100 according to an exemplary embodiment. As illustrated, the mobile device 100 includes an application processor (AP) 110, a memory 120, a storage 130, a modem 140, a user interface 150, and a clock generating circuit 160.

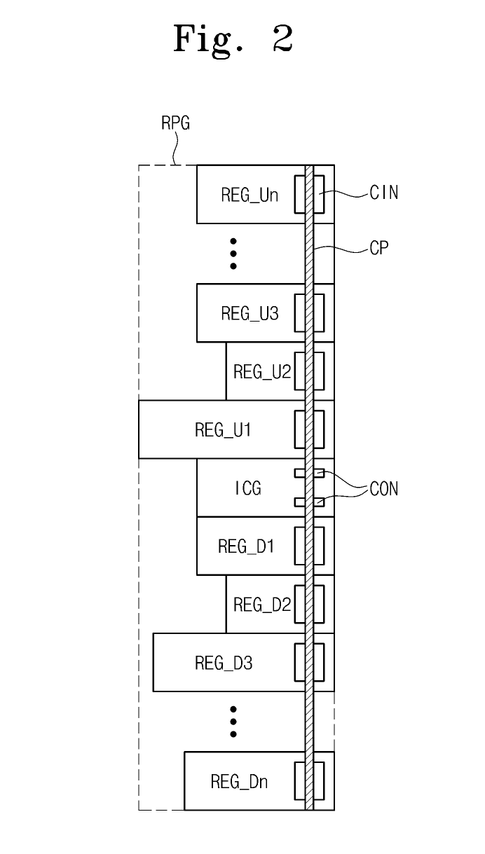

The application processor 110 may control an overall operation of the mobile device 100 and perform logical operations. For example, the application processor 110 may be a system-on-chip (SoC). The application processor 110 may have an aligned clock gating structure. For example, an integrated clock gating (ICG) cell to output a clock signal (e.g., internal clock signal) of the application processor 110 and clock-based cells (e.g., registers, flip-flops, etc.) operating in response to the clock signal output from the integrated clock gating cell may be aligned concentrically in a specific region. The aligned clock gating structure will be described in further detail later with reference to FIGS. 2 to 9.

The memory 120 may communicate with the application processor 110. The memory 120 may be a working memory (or main memory) of the application processor 110 or the mobile device 100. The memory 120 may include a volatile memory such as a static RAM (SRAM), a dynamic RAM (DRAM), and a synchronous DRAM (SDRAM) or a nonvolatile memory such as a phase change RAM (PRAM), a magnetic RAM (MRAM), a resistive RAM (RRAM), and a ferroelectric RAM (FRAM).

The storage 130 may store data desired to be stored in the mobile device 100 for a long period of time. The storage 130 may include a hard disk drive (HDD) or a nonvolatile memory such as a flash memory, a phase change memory (PRAM), a magnetic RAM (MRAM), a resistive RAM (RRAM), and a ferroelectric RAM (FRAM).

For example, the memory and the storage 130 may include the same kind of nonvolatile memory, although it is understood that one or more other exemplary embodiments are not limited thereto. In this case, the memory 120 and the storage 130 may, although not necessarily, include a single semiconductor integrated circuit.

The modem 140 may communicate with an external device according to the control of the application processor 110. For example, the modem 140 may perform wired or wireless communication with an external device. The modem 140 may perform communication based on one of various wireless communication schemes such as long term evolution (LTE), WiMax, global system for mobile communication (GSM), code division multiple access (CDMA), Bluetooth, near field communication (NFC), WiFi, and radio frequency identification (RFID) or one of various wired communication schemes such as universal serial bus (USB), serial AT attachment (SATA), small computer small interface (SCSI), firewire, and peripheral component interconnection (PCI).

The user interface 150 may communicate with a user according to the control of the application processor 110. For example, the user interface 150 may include user input interfaces such as a keyboard, a keypad, a button, a touch panel, a touch screen, a touchpad, a touch ball, a camera, a microphone, a gyroscope sensor, and a vibration sensor. The user interface 150 may include user output interfaces such as liquid crystal display (LCD), organic light emitting diode (OLED) display, active matrix OLED (AMOLED) display, LED, speaker, and motor.

The clock generating circuit 160 may generate and output a clock signal CLK. A clock signal output from the clock generating circuit 160 may be transmitted to the application processor 110.

FIG. 2 illustrates an aligned clock gating structure according to an exemplary embodiment. As illustrated, the aligned clock gating structure may include an integrated clock gating cell ICG and a plurality of clock-based cells REG_U1˜REG_Un and REG_D1˜REG_Dn.

The integrated clock gating cell ICG may receive, for example, an external clock signal from a clock generating circuit (160 in FIG. 1). The integrated clock gating cell ICG may output a clock signal based on the received external clock signal. The integrated clock gating cell ICG may output a clock signal through one or more clock output nodes CON.

The clock-based cells REG_U1˜REG_Un may be placed on one side of the integrated clock gating cell ICG. The clock-based cells REG_U1˜REG_Un may operate in response to a clock signal output from the integrated clock gating cell ICG, e.g., output from a first clock output node CON. The clock-based cells REG_U1˜REG_Un may include elements such as registers and flip-flops. The clock-based cells REG_U1˜REG_Un may receive clock signals through clock input nodes CIN.

The clock-based cells REG_D1˜REG_Dn may be placed on the other side of the integrated clock gating cell ICG. The clock-based cells REG_D1˜REG_Dn may operate in response to a clock signal output from the integrated clock gating cell ICG, e.g., output from a second clock output node CON different from the first clock output node CON. The clock-based cells REG_D1˜REG_Dn may include elements such as registers and flip-flops. The clock-based cells REG_D1˜REG_Dn may receive clock signals through clock input nodes CIN.

The one or more clock output nodes CON of the integrated clock gating cell ICG and the clock input nodes CIN of the clock-based cells REG_U1˜REG_Un and REG_D1˜REG_Dn may be aligned on a straight line. The clock output node CON and the clock input nodes CIN may be commonly connected to a clock gating path CP. That is, a clock signal output to the clock output node CON may be commonly transmitted to the clock input nodes CIN through the clock gating path CP. The clock gating path CP may include a wire or a printed wiring.

The clock-based cells REG_U1˜REG_Un and REG_D1˜REG_Dn may be symmetrically placed around the integrated clock gating cell ICG. The integrated lock gating cell ICG and the clock-based cells REG_U1˜REG_Un and REG_D1˜REG_Dn may be placed adjacent to each other. The integrated clock gating cell ICG and the clock-based cells REG_U1˜REG_Un and REG_D1˜REG_Dn may be aligned on a straight line to constitute a single cell column.

The integrated clock gating cell ICG and the clock-based cells REG_U1˜REG_Un and REG_D1˜REG_Dn may constitute a relative placement group (RPG). The relative placement group (RPG) may be regarded as a group that is related from a design step of an application processor (110 in FIG. 1) to be placed.

The clock based cells REG_U1˜REG_Un and REG_D1˜REG_Dn and/or the integrated clock gating cell ICG in a column or in a relative placement group RPG may be placed intensively excluding another clock based cell or integrated clock gating cell using another clock signal different from the clock signal therebetween. If the integrated clock gating cell ICG and the clock-based cells REG_U1˜REG_Un and REG_D1˜REG_Dn are aligned as shown in FIG. 2, a length of a clock gating path CP along which the clock signal output from the clock gating cell ICG is transmitted to the clock-based cells REG_U1˜REG_Un and REG_D1˜REG_Dn may be minimized. In addition, a length of a clock gating path CP along which a clock signal output from the integrated gating cell ICG is transmitted to the clock-based cell farthest away from the integrated clock gating cell ICG may be minimized.

If the length of the clock gating path CP is minimized, a load such as a resistance component and a capacitance component caused by the clock gating path CP is minimized. Thus, power consumption (e.g., switching power consumption of a clock signal) of the application processor 110 including the aligned clock gating structure is reduced.

If the length of the clock gating path CP is minimized, disturbances such as noise, distortion, and delay generated on the clock gating path CP are minimized. Thus, a difference in skew between clock signals respectively transmitted to the clock-based cells REG_U1˜REG_Un and REG_D1˜REG_Dn is minimized and reliability and operation performance of the application processor 110 having the aligned clock gating structure are enhanced.

If the clock gating cell ICG and the clock-based cells REG_U1˜REG_Un and REG_D1˜REG_Dn are placed concentrically in a specific region, the number of buffers for the clock gating cell ICG and the clock-based cells REG_U1˜REG_Un and REG_D1˜REG_Dn can be decreased. Thus, complexity of the application processor 110 having the aligned clock gating structure is reduced. Moreover, since the placement of cells operating in response to the clock signal output from the clock-based cells REG_U1˜REG_Un and REG_D1˜REG_Dn and macros may be made easy and a data transmission path and a clock signal transmission path are simplified, the complexity of the application processor 110 is reduced.

In order to reduce power consumption and stabilize a skew of clock signals, the clock gating cell ICG and the clock-based cells REG_U1˜REG_Un and REG_D1˜REG_Dn may be concentrically placed such that the length of the clock gating path CP is made less than a reference value. The reference value may be decided by a clock skew that the application processor 110 allows or a clock skew allowed by a design rule. The reference value may be a value which is determined such that the clock signal has a clock skew which are identified by the application processor 110 with a predetermined margin.

As illustrated in FIG. 2, the clock-based cells REG_U1˜REG_Un and REG_D1˜REG_Dn are symmetrically placed around the integrated clock gating cell ICG. However, the expression “symmetrically” is merely exemplary, and one or more other exemplary embodiments are not limited thereto. For example, the placement of the clock-based cells REG_U1˜REG_Un and REG_D1˜REG_Dn may be variously applied as long as the length of the clock gating path CP satisfies the above-mentioned reference value. For example, even when the number of the clock-based cells REG_U1˜REG_Un and REG_D1˜REG_Dn is odd, the clock-based cells REG_U1˜REG_Un and REG_D1˜REG_Dn may be placed with the integrated clock gating cell ICG in or near the center. The number of clock-based cells REG_U1˜REG_Un placed on one side of the integrated cock gating cell ICG and the number of clock-based cells REG_D1˜REG_Dn placed on the other side thereof are not limited.

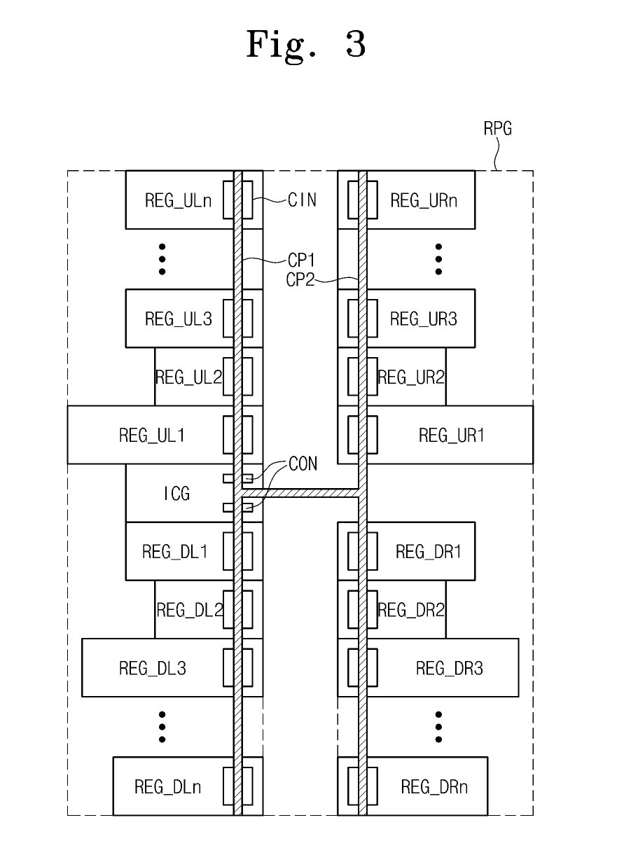

FIG. 3 illustrates an aligned clock gating structure according to another exemplary embodiment. As illustrated, an integrated clock gating cell ICG and clock-based cells REG_UL1˜REG_ULn, REG_DL1˜REG_DLn, REG_UR1˜REG_URn, and REG_DR1˜REG_DRn may constitute two cell columns.

The clock-based cells REG_UL1˜REG_ULn, REG_DL1˜REG_DLn, REG_UR1˜REG_URn, and REG_DR1˜REG_DRn may be placed with the integrated clock gating cell ICG in the center thereof. Clock input nodes CIN of the clock-based cells REG_UL1˜REG_ULn and REG_DL1˜REG_DLn and one or more clock output nodes CON of the integrated clock gating cell ICG may be aligned on a straight line to be commonly connected to a first clock gating path CP1. The integrated clock gating cell ICG and the clock-based cells REG_UL1˜REG_ULn and REG_DL1˜REG_DLn may be placed adjacent to each other to constitute a first cell column.

The clock-based cells REG_UR1˜REG_URn and REG_DR1˜REG_DRn may be placed adjacent to each other. The clock input nodes CIN of the clock-based cells REG_UR1˜REG_URn and REG_DR1˜REG_DRn may be aligned on a straight line to be commonly connected to a second clock gating path CP2. The second clock gating path CP2 may be electrically connected to the one or more clock output nodes CON of the integrated clock gating cell ICG. The clock-based cells REG_UR1˜REG_URn and REG_DR1˜REG_DRn may constitute a second cell column. The second cell column may be parallel to the first cell column.

When the number of clock-based cells in the aligned clock gating structure shown in FIG. 2 increases, the length of the clock gating path CP may increase. As shown in FIG. 3, when the clock-based cells REG_UL1˜REG_ULn, REG_DL1˜REG_DLn, REG_UR1˜REG_URn, and REG_DR1˜REG_DRn are placed in two cell columns, the lengths of the clock gating paths CP1 and CP2 may be minimized.

The integrated clock gating cell ICG and the clock-based cells REG_UL1˜REG_ULn, REG_DL1˜REG_DLn, REG_UR1˜REG_URn and REG_DR1˜REG_DRn may constitute a relative placement group (RPG). The relative placement group (RPG) may be regarded as a group that is related from a design step of an application processor (110 in FIG. 1) to be placed.

In an exemplary embodiment, the number of clock-based cells placed at two cell columns is not limited.

In an exemplary embodiment, an integrated clock gating cell ICG and clock-based cells may constitute three or more columns, and the number of clock-based cells in each of the columns may be the same or different.

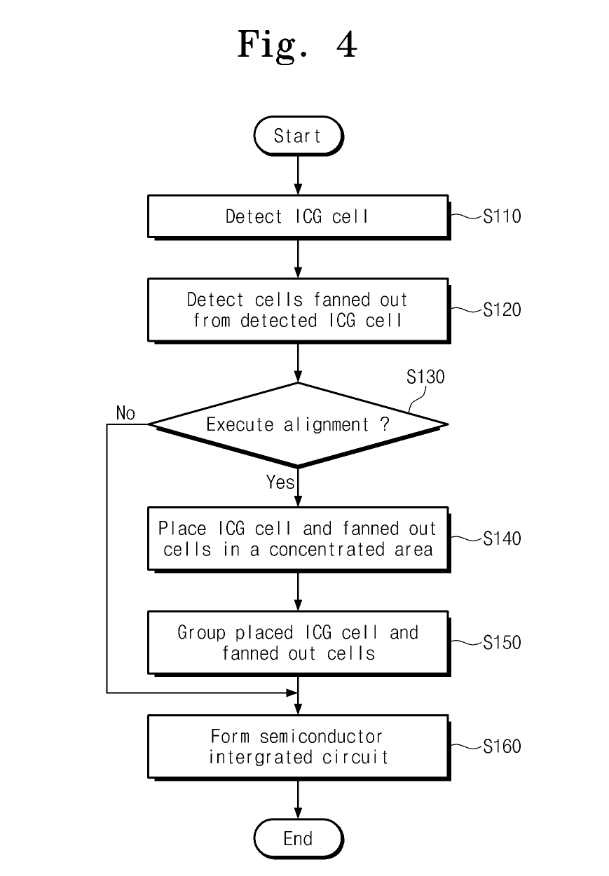

FIG. 4 is a flowchart illustrating a method of forming a semiconductor integrated circuit according to an exemplary embodiment. At operation S110 of the flowchart in FIG. 4, an integrated clock gating (ICG) cell is detected. For example, the ICG cell may be detected from a source code for forming a semiconductor integrated circuit.

At operation S120, fanned out cells are detected from the detected ICG cell. For example, directly fanned-out cells, i.e., cells directly receiving a clock signal, may be detected from an ICG cell. For example, clock-based cells such as fanned-out cells or flip-flops may be detected from an ICG cell. For example, fanned-out cells may be detected from a source code for forming a semiconductor integrated circuit.

At operation S130, it is determined whether alignment is to be executed. If the alignment is not to be executed, the flow proceeds to operation S160. If the alignment is to be executed, the flow proceeds to operation S140.

At operation S140, the ICG cell and the fanned-out cells are placed in a concentrated area.

At operation S150, the placed ICG cell and the placed fanned-out cells are grouped.

At operation S160, a semiconductor integrated circuit is formed.

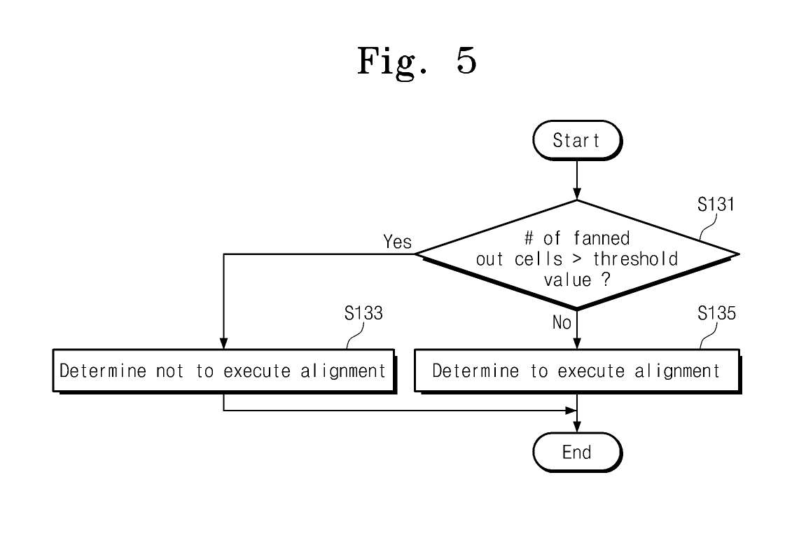

FIG. 5 is a flowchart more specifically illustrating the operation of determining whether alignment is to be executed (operation S130) in FIG. 4. At operation S131 of the flowchart in FIG. 5, it is determined whether the number of the fanned-out cells is greater than a threshold value. If the number of the fanned-out cells is greater than the threshold value, it is determined at operation S133 that the alignment is not to be executed. If the number of the fanned-out cells is not greater than the threshold value, it is determined at operation S135 that the alignment is to be executed.

In an exemplary embodiment, the threshold value is determined by a clock skew that the application processor 110 allows or a clock skew allowed by a design rule.

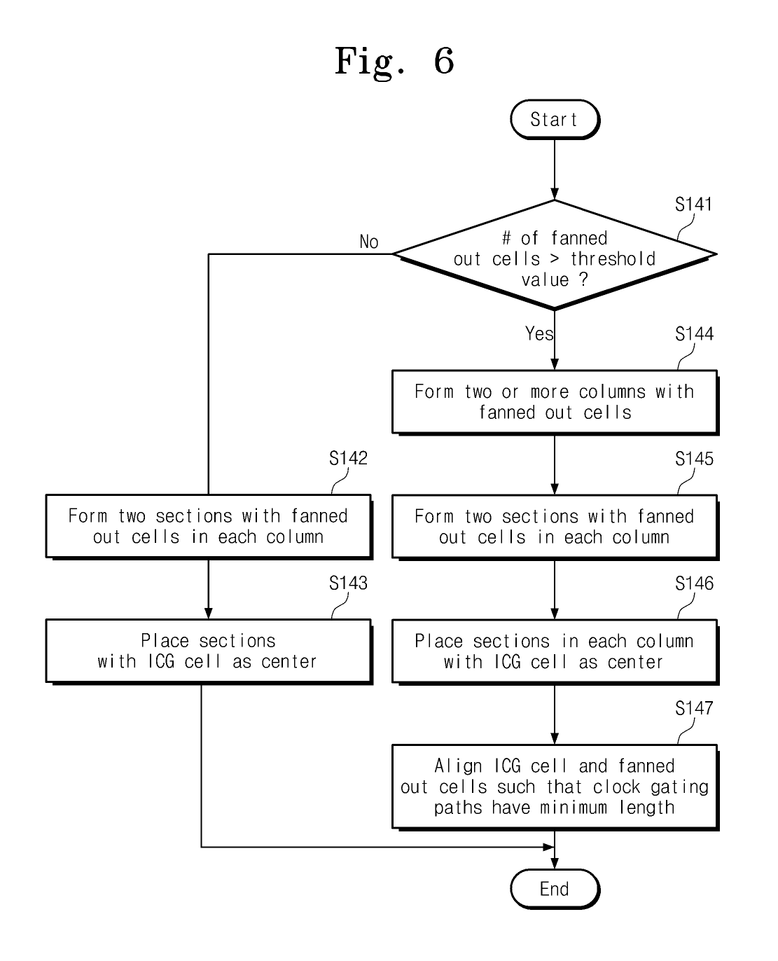

FIG. 6 is a flowchart more specifically illustrating the operation of placing the ICG cell and the fanned-out cells (operation S140) in FIG. 4. At operation S141 of the flowchart in FIG. 6, it is determined whether the number of the fanned-out cells is greater than a threshold value. If the number of the fanned-out cells is greater than the threshold value, the flow proceeds to operation S144. If the number of the fanned-out cells is not greater than the threshold value, the flow proceeds to operation S142.

If the number of the fanned-out cells is not greater than the threshold value, the fanned-out cells are divided into two sections at operation S142. At operation S143, the two sections are placed in the center of the ICG cell. At operation S147, the ICG cell and the fanned-out cells are aligned such that a clock gating path has a minimum length. For example, the ICG cell and the fanned-out cells may be placed and aligned as shown in FIG. 2.

If the number of the fanned-out cells is greater than the threshold value, the fanned-out cells constitute two or more columns at operation S144. At operation S145, the fanned-out cells are divided into two sections in each column. At operation S147, the ICG cell and the fanned-out cells are aligned such that the clock gating path has a minimum length. For example, the ICG cell and the fanned-out cells may be placed and aligned as shown in FIG. 3.

In an exemplary embodiment, the threshold value is determined by a clock skew that the application processor 110 allows or a clock skew allowed by a design rule.

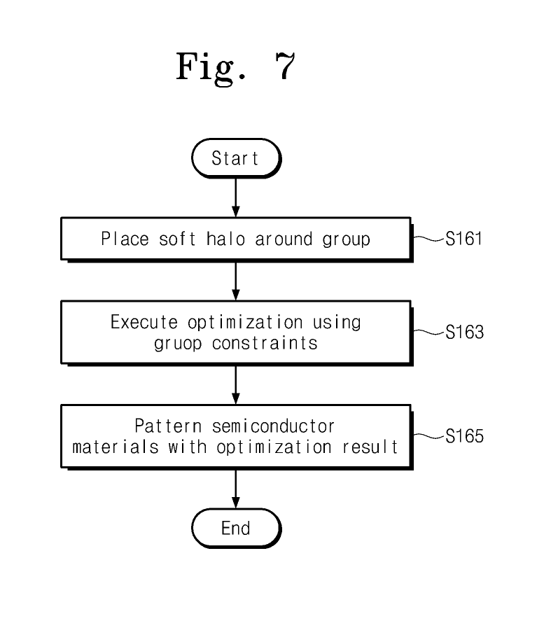

FIG. 7 is a flowchart more specifically illustrating the operation of forming a semiconductor integrated circuit (operation S160) in FIG. 4. At operation S161 of the flowchart in FIG. 7, a soft halo is placed around the group formed by the ICG cell and the fanned-out cells. In an exemplary embodiment, the soft halo may be an area in which placement of other cells and other macros is not allowed and placement of elements such as buffers for optimizing the group formed by the ICG cell and the fanned-out cells is allowed.

At operation S163, optimization is executed using group constraints. For example, the optimization may be executed using a group formed by an integrated clock gating (ICG) cell and fanned-out cells and additional constraints made by adding soft halo around the group to existing constraints. That is, the optimization is executed within the range where placement of the group formed by the ICG cell and the fanned-out cells and the soft halo around the group is not changed.

At operation S165, a semiconductor material is patterned using a result of the optimization. If the patterning is conducted, a semiconductor integrated circuit may be formed.

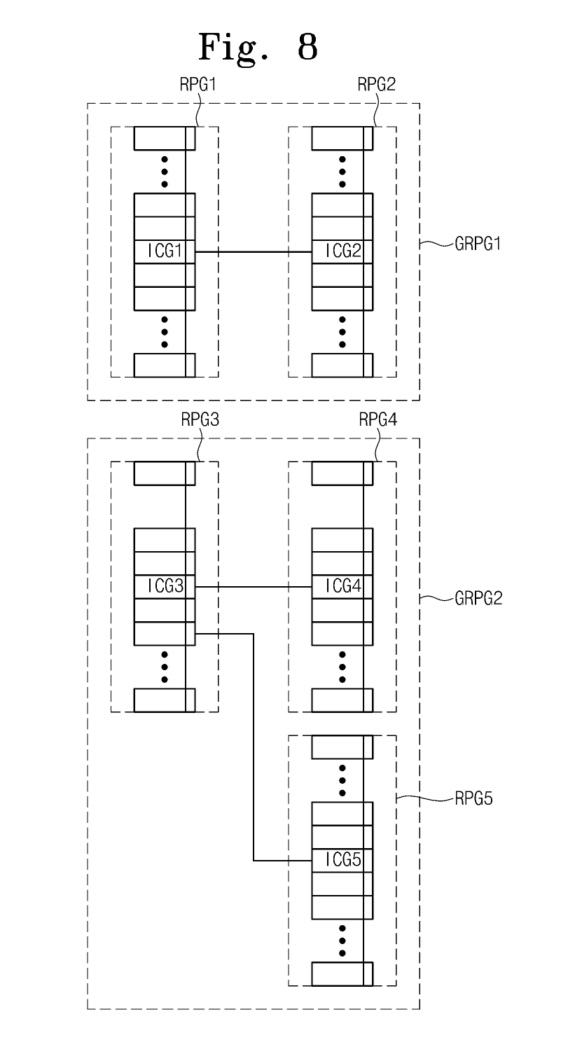

FIG. 8 illustrates an aligned clock gating structure according to another exemplary embodiment. As illustrated, a plurality of relative placement groups RPG1 and RPG2 or RPG3˜RPG5 may constitute global relative placement group GRPG1 or GRPG2, respectively. The global relative placement group GRPG1 or GRPG2 may be regarded as a group that is related from a design step of an application processor (110 in FIG. 1) to be placed.

The relative placement group RPG1 may include an integrated clock gating cell ICG1 and a plurality of clock-based cells. The relative placement group RPG2 may include an integrated clock gating cell ICG2 and a plurality of clock-based cells. The integrated clock gating cells ICG2 may operate by directly receiving a clock signal output from the integrated clock gating cell ICG1. The integrated clock gating cell ICG2 may be a cell fanned out from the integrated clock gating cell ICG2. That is, one cell column and another cell column fanned out from a corresponding cell column may constitute one global relative placement group GRPG1.

The relative placement group RPG3 may include an integrated clock gating cell ICG3 and a plurality of clock-based cells. The relative placement group RPG4 may include an integrated clock gating cell ICG4 and a plurality of clock-based cells. The integrated placement group RPG5 may include an integrated clock gating cell and a plurality of clock-based cells.

The integrated clock gating cells ICG4 may operate by directly receiving a clock signal output from the integrated clock gating cell ICG3. The integrated clock gating cell ICG4 may be a cell fanned out from the integrated clock gating cell ICG3. The integrated clock gating cell ICG5 may operate by directly receiving a clock signal output from the cell fanned out from the integrated clock gating cell ICG3. The integrated clock gating cell ICG5 may be a cell fanned out from the integrated clock gating cell ICG3. That is, one cell column and at least two cell columns fanned out from a corresponding cell column may constitute one global relative placement group GRPG2. The fanned-out cell columns may be directly fanned out from the integrated clock gating cell ICG3 or may be fanned out through the cell fanned out from the integrated clock gating cell ICG3.

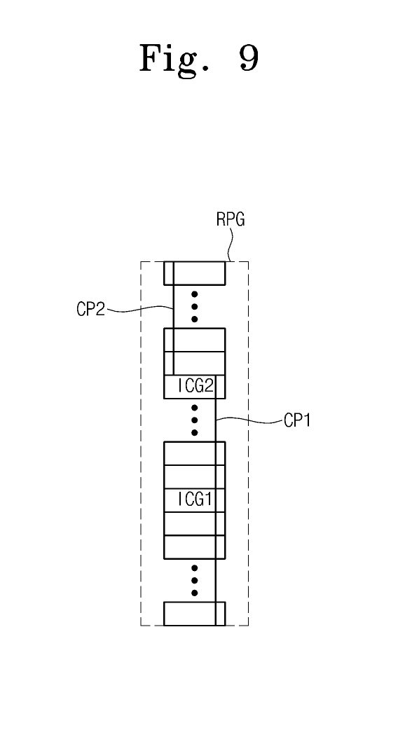

FIG. 9 illustrates an aligned clock gating structure according to another exemplary embodiment. As illustrated, a plurality of integrated clock gating cells ICG1 and ICG2 may constitute one cell column and one relative placement group.

The integrated gating cell ICG2 may be a cell fanned out from the integrated clock gating cell ICG1. Clock-based cells fanned out from the integrated clock gating cell ICG2 and the integrated clock gating cell ICG2 may constitute one cell together with clock-based cells fanned out from the integrated clock gating cell ICG1 and the integrated clock gating cell ICG2.

The integrated clock gate cell ICG1, the clock-based cells fanned out from the integrated clock gating cell ICG2, and the integrated clock gating cell ICG2 may be aligned on a straight line to be commonly connected to a first clock gating path CP1. The integrated clock gating cell ICG2 and the clock-based cells fanned out from the integrated clock gating cell ICG2 may be aligned on a straight line to be commonly connected to a second clock gating path CP2.

In an exemplary embodiment, in FIG. 9, it is shown that the integrated clock gating cell ICG2 directly receives a clock signal from the integrated clock gating cell ICG1. However, it is understood that one or more other exemplary embodiments are not limited thereto. For example, the integrated clock gating cell ICG2 may receive a clock signal through a clock-based cell fanned out from the integrated clock gating cell ICG1.

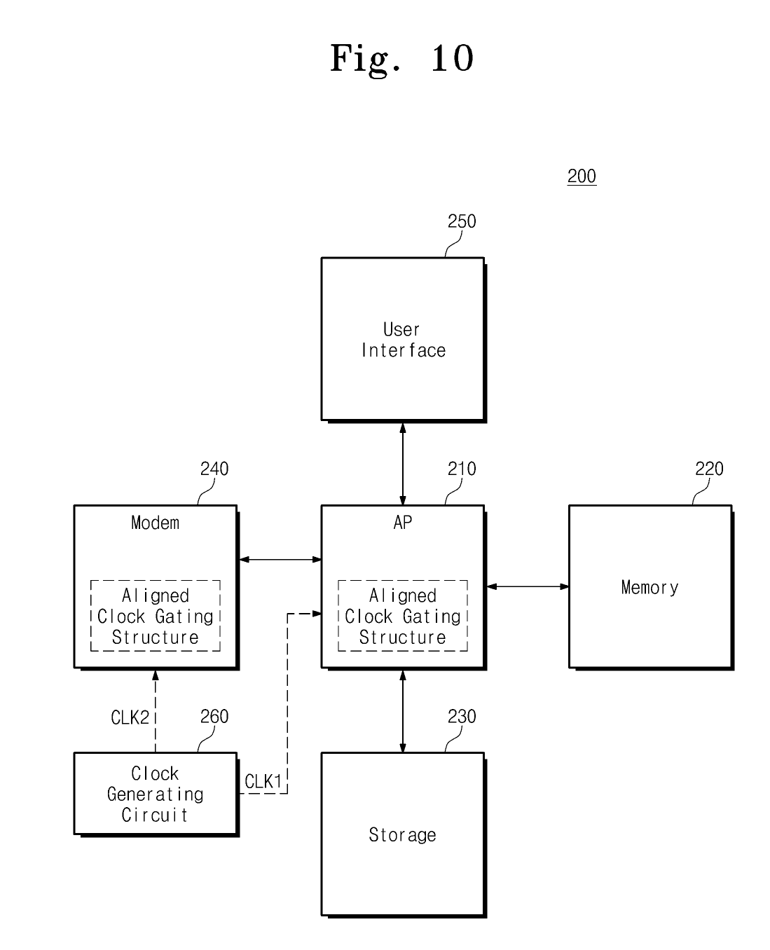

FIG. 10 is a block diagram of a mobile device 200 according to another exemplary embodiment. As illustrated, the mobile device 200 includes an application processor (AP) 210, a memory 220, a storage 230, a modem 240, a user interface 250, and a clock generating circuit 260.

As compared to the mobile device 100 described with reference to FIG. 1, the clock generating circuit 260 may output plural clock signals CLK1 and CLK2. The application processor 210 includes an aligned clock gating structure. The application processor 210 may operate in response to a first clock signal CLK1 output from the clock generating circuit 260. The modem 240 includes an aligned clock gating structure. The modem may operate in response to a second clock signal CLK2 output from the clock generating circuit 260.

It is understood that, in addition to the application processor 210 and the modem, any element using a clock, among the elements of the mobile device 200, may have an aligned clock gating structure.

In an exemplary embodiment, the application processor 210 and the modem 240 may be integrated into a semiconductor device.

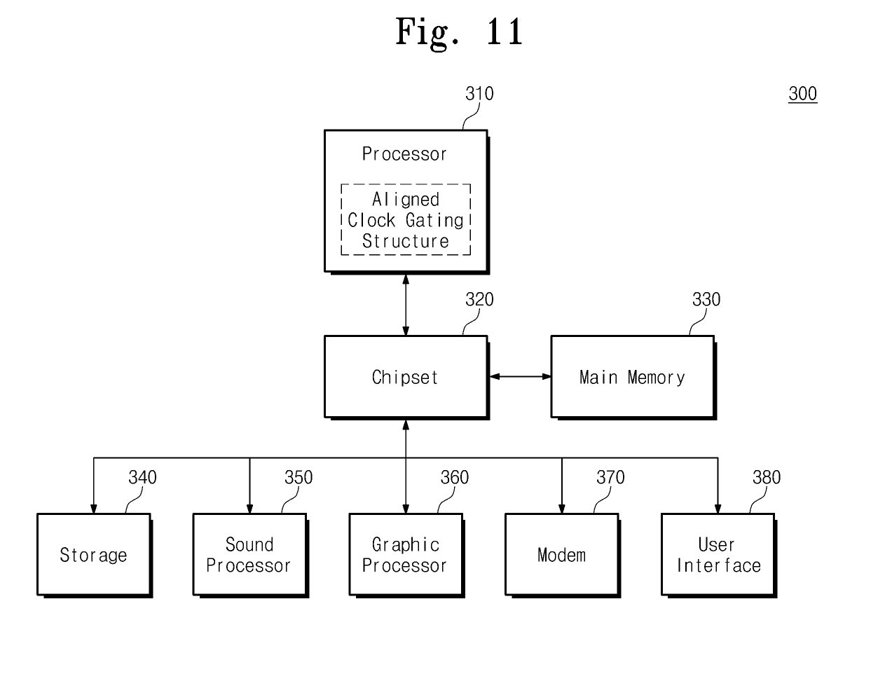

FIG. 11 is a block diagram of a computing system 300 according to an exemplary embodiment. As illustrated, the computing system 300 includes a processor 310, a chipset 320, a main memory 330, a storage 340, a sound processor 350, a graphic processor 360, a modem 370, and a user interface 380.

The processor 310 may control the overall operation of the computing system 300 and perform a logical operation. The processor 310 may have an aligned clock gating structure. It is understood that, in addition to the processor 310, bay element using a clock, among the elements of the computing system 300, may have an aligned clock gating structure. If an aligned clock gating structure is provided, power consumption and complexity of the computing system 300 are reduced and operation performance and reliability of the computing system 300 are enhanced.

The chipset 320 may operate according to the control of the processor 310.

The chipset 320 may mediate communication between the processor 310 and other elements.

The main memory 330 may be a working memory of the computing system 300. The main memory 330 may be a random access memory (RAM) such as DRAM, SRAM, PRAM, MRAM, RRAM, and FRAM.

The storage 340 may be used to retain data for a long period of time. The storage 340 may include a nonvolatile memory such as flash memory, MRAM, PRAM, RRAM, and FRAM.

The sound processor 350 may process sound according to the control of the processor 310. The sound processor 350 may compress, decompress, encode, and decode sound data.

The graphic processor 360 may process graphic according to the control of the processor 310. The graphic processor 360 may compress, decompress, encode, decode, and track graphic data.

The modem 370 may perform wired or wireless communication with an external device according to the control of the processor 310.

The user interface 380 may output a signal to an external entity or receive a signal from an external entity according to the control of the processor 310.

As described so far, an integrated clock gating cell and clock-based cells are concentrically placed to decrease a length of a clock gating path along which a clock signal is transmitted. Thus, power consumption of a semiconductor integrated circuit and a computing system is reduced. Moreover, since a difference in skew between clock signals is reduced due to the decreased length of the clock gating path, reliability and operation performance of the computing system are enhanced. If the clock-based cells are concentrically placed, a clock tree structure is simplified to reduce complexity of the semiconductor integrated circuit and the computing system.

While exemplary embodiments have been particularly shown and described above, it will be apparent to those of ordinary skill in the art that various changes in form and detail may be made therein without departing from the spirit and scope of the inventive concepts as defined by the following claims.

What is claimed is:

1. A semiconductor integrated circuit comprising:
a first integrated clock gating cell comprising a first clock output node; and
first clock-based cells each comprising a first clock input node,
wherein the first clock output node of the first integrated clock gating cell and the first clock input nodes of the first clock-based cells are aligned on a straight line and commonly connected to a first clock gating path.

2. The semiconductor integrated circuit as set forth in claim 1, wherein the first integrated clock gating cell and the first clock-based cells are adjacent to each other.

3. The semiconductor integrated circuit as set forth in claim 1, wherein the first clock gating path includes a wire.

4. The semiconductor integrated circuit as set forth in claim 1, wherein the first clock-based cells include registers each operating based on a clock.

5. The semiconductor integrated circuit as set forth in claim 1, wherein the first clock-based cells include flip-flops each operating based on a clock.

6. The semiconductor integrated circuit as set forth in claim 1, further comprising:
second clock-based cells each comprising a second clock input node,
wherein the second clock input nodes of the second clock-based cells are aligned on a straight line and commonly connected to a second clock gating path, and
wherein the second clock gating path is electrically connected to the first clock output node of the first integrated clock gating cell.

7. The semiconductor integrated circuit as set forth in claim 6, wherein the first integrated clock gating cell and the first clock-based cells constitute a first cell column, and the second clock-based cells constitute a second cell column parallel to the first cell column.

8. The semiconductor integrated circuit as set forth in claim 1, further comprising:
a second integrated clock gating cell comprising a third clock input node at a first end thereof and a second clock output node at a second end thereof; and
second clock-based cells each comprising a second clock input node,
wherein the second clock output node of the second integrated clock gating cell and the second clock input nodes of the second clock-based cells are aligned on a straight line and connected to a second clock gating path.

9. The semiconductor integrated circuit as set forth in claim 8, wherein the third clock input node of the second integrated clock gating cell is electrically connected to the first clock output node of the first integrated clock gating cell.

10. The semiconductor integrated circuit as set forth in claim 8, wherein the third clock input node of the second integrated clock gating cell is electrically connected to a third clock output node of one of the first clock-based cells.

11. The semiconductor integrated circuit as set forth in claim 1, wherein one of the first clock-based cells comprises the clock input node at a first end thereof and a third clock output node at a second end thereof.

12. The semiconductor integrated circuit as set forth in claim 11, further comprising:
a second integrated clock gating cell comprising a second clock output node,
second clock-based cells each comprising a second clock input node,
wherein the second clock input nodes of the second clock-based cells are aligned with the second clock output node of the second integrated clock gating cell on a straight line.

13. The semiconductor integrated circuit as set forth in claim 12, wherein the first integrated clock gating cell, the second integrated clock gating cell, the first clock-based cells, and the second clock-based cells are adjacent to each other on a straight line to constitute a single cell column.

14. A computing system comprising:
a main memory;
a storage;
a processor configured to control the main memory and the storage;
a modem configured to communicate with a first external entity according to a control of the processor;
a user interface configured to receive a signal from a second external entity and output a signal to the second external entity according to a control of the processor; and
a clock generating circuit configured to generate a clock signal and transmit the generated clock signal to at least one of the processor and the modem,
wherein the at least one of the processor and the modem comprises an aligned clock gating tree structure operating in response to the transmitted clock signal,
wherein the aligned clock gating tree structure comprises an integrated clock gating cell configured to receive the clock signal and output a gated clock signal and a plurality of clock-based cells configured to receive the output gated clock signal from the integrated clock gating cell, and
wherein the integrated clock gating cell and the plurality of clock-based cells are concentrically arranged such that a length of a longest clock gating path along which the gated clock signal is transmitted to the clock-based cells from the integrated clock gating cell is equal to or less than a reference value.

15. The computing system as set forth in claim 14, wherein an output node of the gated clock signal of the integrated clock gating cell and input nodes of the gated clock signal of the clock-based cells are aligned on a straight line and commonly connected to the clock gating path.

16. A semiconductor integrated circuit comprising:
a first integrated clock gating cell configured to output a gated clock signal along a first clock gating path that is a straight line; and
first clock-based cells each configured to receive the output gated clock signal along the first clock gating path,
wherein the first integrated clock gating cell and the first clock-based cells are arranged such that a longest transmission length on the first clock gating path along which the gated clock signal is transmitted to the first clock-based cells from the first integrated clock gating cell is equal to or less than a reference value.

17. The semiconductor integrated circuit as set forth in claim 16, further comprising:
second clock-based cells each configured to receive the output gated clock signal along a second clock gating path that is a straight line,
wherein the second clock-based cells are arranged that a longest transmission length on the second clock gating path along which the gated clock signal is transmitted to the second clock-based cells from the first integrated clock gating cell is equal to or less than the reference value, and
wherein the second clock gating path is electrically connected to the first integrated clock gating cell.

18. The semiconductor integrated circuit as set forth in claim 16, further comprising:
a second integrated clock gating cell configured to receive the gated clock signal output from the first integrated clock gating cell, and to output the received gated clock signal along a second clock gating path that is a straight line; and
second clock-based cells each configured to receive the gated clock signal, output from the second integrated clock gating cell, along the second clock gating path.

19. The semiconductor integrated circuit as set forth in claim 18, wherein the second integrated clock gating cell is configured to receive the gated clock signal along the first clock gating path from one of the first clock-based cells.

20. The semiconductor integrated circuit as set forth in claim 18, wherein the second integrated clock gating cell is configured to receive the gated clock signal along a path from the first integrated clock gating cell that does not include any clock-based cells.
